(19) United States
(12) Patent Application Publication
(10) Pub. No.: US 2005/0145867 A1
(43) Pub. Date: Jul. 7, 2005

(54) Planar package structure for high power light emitting diode

(75) Inventors: Po-Hung Yau, KaoHsiung (TW); Jauh-Jung Yang, Taipei (TW); Yu-Cheng Lin, Taipei (TW); I-Kai Pan, KaoHsiung (TW)

Correspondence Address: BRUCE H. TROXELL, SUITE 1404, 5205 LEESBURG PIKE, FALLS CHURCH, VA, 22041, US

(73) Assignee: Industrial Technology Research Institute

(21) Appl. No.: 10/812,921

(22) Filed: Mar. 31, 2004

(30) Foreign Application Priority Data
Dec. 26, 2003 (TW) 92136954

(51) Int. Cl. H01L 33/00

(52) U.S. Cl. 257/98

(57) ABSTRACT

A planar package structure for high power light emitting diode, comprising: a substrate; a package material; a light emitting diode chip disposed on the substrate, having a main light emitting surface served as a light source; and a planar optical modulation unit disposed on the package material, so that the planar optical modulation unit is above the main light emitting surface, and utilized for modulating the optical phase of the light source. The planar optical modulation unit can perform a refractive optical phase modulation or a diffractive optical phase modulation such that a thin and planar high power light emitting diode package element with function of optical phase modulation is obtained.

### 1. FIELD OF THE INVENTION

The present invention relates to a planar package structure for high power light emitting diode, and in particular to a thin and planar package structure for high power light emitting diode, which structure is provided with various magnification factors and optical functions by means of the combination of a light emitting diode (LED) chip and a planar lens which has various focal lengths designed by optical calculation and modulation of binary optics and planar lens.

### 2. BACKGROUND OF THE INVENTION

Conventional package structure for high power LED makes LED lamps have good light emitting directivity such that the light source from the LED chip achieves fine utilization efficiency. However, such package structure is too thick and can only make divergent light beams being converged without any particular functions. Therefore, the light source of high power LED with conventional package structure cannot satisfy the requirements of products with high brightness and compact size in the future.

As disclosed in U.S. Pat. No. 6,531,328, the conventional LED package structure comprises resin covering the LED chip. An LED lamp including ordinary resin lenses is used in a lens-type package for mainly converging the wide-angled light beams emitted from the chip to narrow-angle ones thus obtaining an LED element with a specific emitting angle.

Another LED package disclosed in U.S. Pat. No. 6,562,643 is also a conventional resin lens-type package, which cannot minimize the thickness of an LED element.

In summary, the conventional package structure for high power LED has at least the following drawbacks:

As the LED lamp is utilized with ordinary resin lenses, the volume of package structure is too large and the degree of freedom of the product is reduced.

The conventional package structure can only be applied to converge the divergent light beams without any other particular function.

The conventional package structure cannot achieve the requirement of planarization so that variety of the product is greatly limited.

When a point light source is expanded in application to a surface light source, the modulation for achieving light uniformity is difficult. And, for a large-sized backlight module, too many conventional LEDs are needed such that the production cost of the module is increased.

### SUMMARY OF THE INVENTION

Accordingly, the major object of the invention is to provide a planar package structure for high power LED. By means of a planar optical modulation unit designed by optical calculation of binary optics and planar lens, the volume of the LED package structure is reduced such that the production cost can be reduced and the performance is promoted.

A secondary object of the invention is to provide a planar package structure for high power LED, capable of adjusting various magnification factors and optical functions of a light source to match with various applications.

Another object of the invention is to provide a planar package structure for high power LED, capable of achieving the requirement of planarization to increase application diverseness of the product.

Another object of the invention is to provide a planar package structure for high power LED, which can be used in a large-sized backlight module. By means of optical modulation of the micro-lens structure, the light spot of the LED is magnified (light spot magnification) to reduce the difficulty of modulation for light uniformity when a point light source is expanded in application to a surface light source module, and to reduce the amount of LED used in a large-sized backlight module.

Yet another object of the invention is to provide a planar package structure for high power LED, capable of increasing the output brightness thereof.

To achieve the above-mentioned objects, the invention provides a planar package structure for high power light emitting diode, comprising a substrate; a package material; a light emitting diode chip disposed on the substrate, having a main light emitting surface served as a light source; and a planar optical modulation unit disposed on the package material, so that the planar optical modulation unit is above the main light emitting surface, and utilized for modulating the optical phase of the light source. The planar optical modulation unit can perform a refractive optical phase modulation or a diffractive optical phase modulation such that a thin and planar high power light emitting diode package element with various optical modulation functions is achieved.

A detailed description is given in the following embodiments with reference to the accompanying drawings.

### BRIEF DESCRIPTION OF THE DRAWINGS

The present invention can be much more understood by the subsequent detailed description and embodiments with reference numerals made to the accompanying drawings, wherein:

FIG. 1 is a cross section of the first embodiment of the invention;

FIG. 2 is a cross section of the second embodiment of the invention;

FIG. 3 is a cross section of the third embodiment of the invention;

FIG. 4 is a cross section of the fourth embodiment of the invention; and

FIG. 5 is a cross section of the fifth embodiment of the invention.

### DESCRIPTION OF THE PREFERRED EMBODIMENT

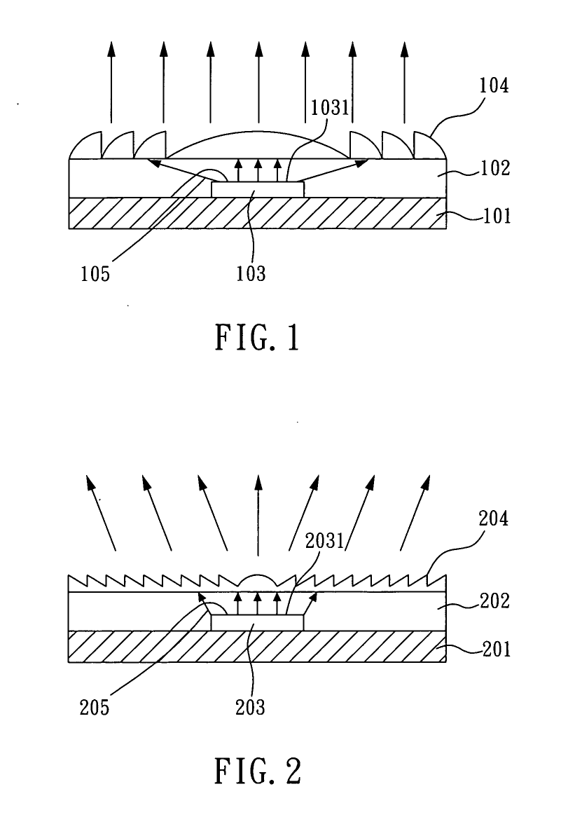

Referring to FIG. 1, the planar package structure for high power LED of the first embodiment of the invention comprises: a substrate 101, a package material 102, a LED chip 103, and a planar optical modulation unit 104, wherein the LED chip 103 is disposed on the substrate 101 and has a main light emitting surface 1031 served as a light source 105. The planar optical modulation unit 104 is disposed above the main light emitting surface 1031 by the package material 102 and performs a refractive optical phase modulation or a diffractive optical phase modulation for the light source 105 by means of calculation of binary optical phase compensation. In the first embodiment of the invention, the planar optical modulation unit 104 is designed as a Fresnel lens structure for performing a refractive optical phase modulation or a diffractive optical phase modulation. When the planar optical modulation unit 104 performs a refractive optical phase modulation, it makes the planar structure made up of thin arc rings on the surface of conventional lens to form such as projector or magnifier in front of TV screen. The planar optical modulation unit 104 can be made on a metal mold by Lithographice Galvanoformung and Abformung (LIGA) technique in advance, then the package material 102 is combined integrally with the LED chip 103 by hot pressing, ejection or mold filling. Usually, the package material 102 is made of transparent resin or polymer material.

In the following embodiments of the invention, because most elements are the same as those in the first embodiment, such as substrates 201, 301, 401, 501 are the same as the substrate 101, package materials 202, 302, 402, 502 are the same as the package material 102, LED chips 203, 303, 403, 503a, 503b are the same as the LED chip 103, main light emitting surfaces 2031, 3031, 4031, 5031a, 5031b are the same as the main light emitting surface 1031, descriptions for the structure and function thereof are eliminated thereafter.

Referring to FIG. 2, which is a cross section of the second embodiment of the invention, the planar optical modulation unit 204 is also a Fresnel lens structure as stated in the first embodiment. However, it performs a diffractive optical phase modulation, i.e. it is formed by a series of concentric rings, wherein the distance between rings and the width of rings can be varied according to the wavelength of the light source 205 to be modulated, the requirement of convergence or divergence of the light source 205 or the different patterns of diffraction, to process applications such as splitting light beams or adjusting light beams, etc. The planar optical modulation unit 204 is also planar.

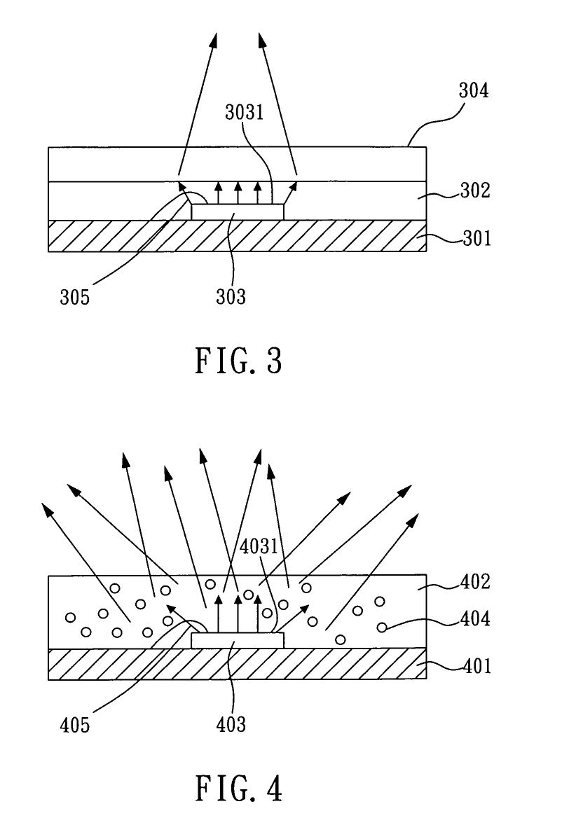

Referring to FIG. 3, which is a cross section of the third embodiment of the invention, the planar optical modulation unit 304 is a lens structure with a gradient refractive index, which is made by doping impurities into a plate-like dielectric to obtain a gradient refractive index. The designed gradient refractive index can refract light beams from the light source 305 to an intended position, i.e. the planar optical modulation unit 304 becomes a lens which has some focal length. Thus, a lens structure with gradient refractive index is formed and the object of flatting the whole package structure is accomplished.

Referring to FIG. 4, which is a cross section of the fourth embodiment of the invention, wherein the package material 402 is doped with a plurality of diffusion particles 404 for scattering light beams from the light source 405, to achieve the effect of diffusing light source. The structure formed by the package material 402 and the diffusion particles 404 is an integrally packaged structure, thus the objects of flatting and integrally packaging are accomplished simultaneously for high power LED.

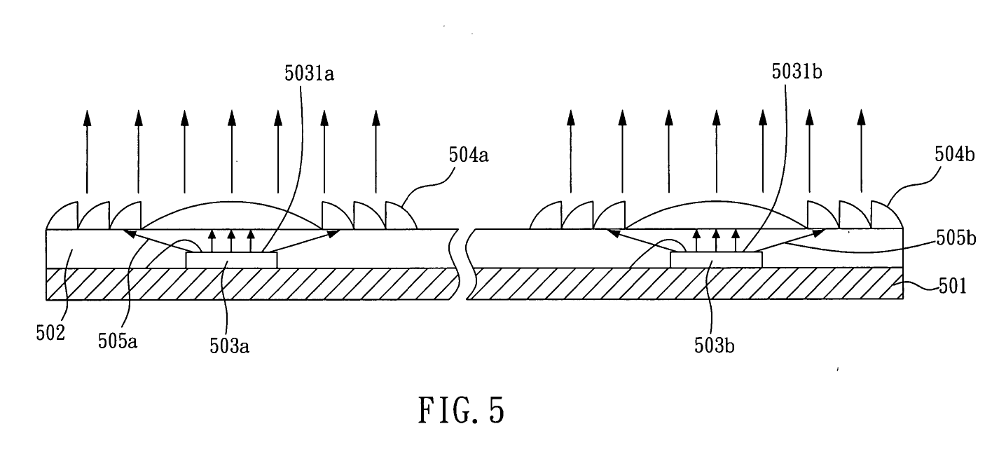

Referring to FIG. 5, which is a cross section of the fifth embodiment of the invention, the planar optical modulation units 504a, 504b are one by one corresponding to the main light emitting surfaces 5031a, 5031b of the LED chips 503a, 503b to perform optical phase modulation for the light source 505a, 505b, respectively, and an array structure of high power LEDs is formed by integrally packaging the structure with the package material 502. This array structure can be applied in a large-sized backlight module and makes the high power LEDs from point light sources close to a surface light source, thus jumping out of conventional application frame of changing point light sources to a line light source then changing line light sources to a surface light source. The array structure can also reduce light loss and simplify the module structure as well as reduce the amount of high power LED used in a large-sized backlight module. Therefore, it contributes to the development of the future LCD backlight module technology and meets the requirements of compact size, low cost, high brightness, and power saving, etc.

As a summary, the planar package structure for high power LED of the invention has a planar optical modulation unit designed by optical calculation of binary optics and planar lens, to accomplish the object of planarization and perform various magnification factors and optical functions for the light source. The invention can also be applied to a large-sized backlight module as a surface light source for reducing the difficulty in light uniformity modulation and can be mass-produced.

While the invention has been described by way of examples and in terms of the preferred embodiments, it is to be understood that the invention is not limited to the disclosed embodiments, for example, the planar optical modulation unit may use concentric circles rather than concentric rings, or the package material made by other materials can be used. To the contrary, it is intended to cover various modifications and similar arrangements which would be apparent to those skilled in the art. Therefore, the scope of the appended claims should be accorded the broadest interpretation so as to encompass all such modifications and similar arrangements.

1. A planar package structure for high power light emitting diode, comprising:
a substrate;
a package material;
a light emitting diode chip disposed on the substrate, having a main light emitting surface served as a light source; and
a planar optical modulation unit disposed on the package material, so that the planar optical modulation unit is above the main light emitting surface, and utilized for modulating the optical phase of the light source.

2. The planar package structure for high power light emitting diode of claim 1, wherein the package material is made of transparent resin.

3. The planar package structure for high power light emitting diode of claim 1, wherein the package material is made of polymer material.

4. The planar package structure for high power light emitting diode of claim 1, wherein the planar optical modulation unit performs a refractive optical phase modulation.

5. The planar package structure for high power light emitting diode of claim 1, wherein the planar optical modulation unit performs a diffractive optical phase modulation.

6. The planar package structure for high power light emitting diode of claim 1, wherein the planar optical modulation unit is a Fresnel lens structure.

7. The planar package structure for high power light emitting diode of claim 1, wherein the planar optical modulation unit is a lens structure with a gradient refractive index.

8. A planar package structure for high power light emitting diode, comprising:
a substrate;
a package material;
a plurality of light emitting diode chips disposed on the substrate, each light emitting diode chip having a main light emitting surface served as a light source; and
a plurality of planar optical modulation units disposed on the package material, so that each of the planar optical modulation units is above each of the main light emitting surface respectively, and utilized for modulating the optical phase of each of the light sources.

9. The planar package structure for high power light emitting diode of claim 8, wherein the package material is made of transparent resin.

10. The planar package structure for high power light emitting diode of claim 8, wherein the package material is made of polymer material.

11. The planar package structure for high power light emitting diode of claim 8, wherein each of the planar optical modulation units performs a refractive optical phase modulation.

12. The planar package structure for high power light emitting diode of claim 8, wherein each of the planar optical modulation units performs a diffractive optical phase modulation.

13. The planar package structure for high power light emitting diode of claim 8, wherein each of the planar optical modulation units is a Fresnel lens structure.

14. The planar package structure for high power light emitting diode of claim 8, wherein each of the planar optical modulation units is a lens structure with a gradient refractive index.

15. A planar package structure for high power light emitting diode, comprising:
a substrate;
a light emitting diode chip disposed on the substrate, having a main light emitting surface served as a light source; and
a package material disposed on the main light emitting surface, and doped with a plurality of scattering particles for scattering light beams from the light source.

16. The planar package structure for high power light emitting diode of claim 15, wherein the package material is made of transparent resin.
The planar package structure for high power light emitting diode of claim 15, wherein the package material is made of polymer material.
